(19) United States
(12) Patent Application Publication
(10) Pub. No.: US 2007/0131899 A1
(43) Pub. Date: Jun. 14, 2007

(54) Composition for polishing semiconductor layers

(76) Inventor: Jinru Bian, Newark, DE (US)

Correspondence Address: ROHM AND HAAS ELECTRONIC MATERIALS;CMP HOLDINGS, INC., 451 BELLEVUE ROAD, NEWARK, DE, 19713, US

(21) Appl. No.: 11/301,781

(22) Filed: Dec. 13, 2005

(51) Int. Cl. C09K 13/00; H01L 21/302; H01L 21/461

(52) U.S. Cl. 252/79.1; 438/692

(57) ABSTRACT

The aqueous polishing composition is useful for polishing semiconductor substrates. The polishing composition includes 0.05 to 50 weight percent abrasive; and 0.001 to 2 weight percent lambda type carrageenan, the lambda type carrageenan having a concentration useful for accelerating TEOS removal rate.

### BACKGROUND OF THE INVENTION

The invention relates to polishing compositions for modifying the removal rate of silicon oxide-containing layers in semiconductor devices. It also relates to chemical mechanical planarizing (CMP) processes for removing silicon oxide-containing layers from underlying layers, such as silicon carbide (SiC), silicon carbide nitride (SiCN), and silicon nitride (Si₃N₄).

Chip fabricators use multiple chemical-mechanical-planarization (CMP) steps to planarize wafers to facilitate the production of flat substrate surfaces. These flat surfaces facilitate the production of multi-level integrated circuits without the detrimental distortion experienced from applying dielectric to uneven substrates.

The CMP process is typically carried out in a two-step sequence to improve polishing performance. First, the polishing process uses a “first-step” slurry specifically designed to rapidly remove the interconnect metal, such as copper. After this initial copper removal step, a “second-step” slurry removes the barrier layer. Typically, the second-step slurries have selectivity to remove the barrier layer without adversely impacting the physical structure or electrical properties of the interconnect structure by “dishing” the interconnect metal. The removal rate of the barrier versus the removal rate of the metal interconnect or the dielectric layer is known as the selectivity ratio. For purposes of this specification removal rate refers to a removal rate as change of thickness per unit time, such as, Angstroms per minute.

After removing the barrier layer, the slurry typically removes an underlying layer, such as a silicon oxide-containing material. For the purposes of this invention, silicon oxide-containing materials include materials derived from silanes such as tetratethylorthosilicate (TEOS) and other silicon oxide-containing coatings used to fabricate semiconductors. Unfortunately, slurries that remove silicon oxide-containing materials at high removal rates tend to also remove underlying masks, caps, such as silicon carbide nitride (SiCN), silicon nitride (SiN) and silicon carbide (SiC). The uncontrolled removal of these underlying layers can have a detrimental impact upon the integrated circuit's ultimate performance.

CMP polishing compositions have proposed adding carrageenan for various purposes. For example, Thomas et al., in U.S. Pub. No. 2005/0104048, disclose adding carrageenan gum to reduce copper dishing. These proposed usages relates to copper removal and not to the removal of a TEOS layer

In several low k dielectric and ultra-low k integration schemes, depositing capping materials on top of the dielectrics protects the dielectrics from mechanical damage. Then above the capping layer a mask layer, such as TEOS, defines area for dielectric or interconnect metal within the integrated circuit by removing the mask layer with a patterned etch process. After etching, a barrier layer covers the substrate and then a metal layer, such as copper, fills the channels or vias. For efficacious CMP, these semiconductor integration schemes typically require the selective removal of mask layers, such as TEOS mask layers with low-level dishing of metal interconnects and minimal removal of a bottom capping layer (such as SiCN, or SiC).

Since silicon oxide-containing layers, such as TEOS, have higher dielectric constants than the low k and ultra-low k materials, it is advisable to keep these TEOS layers as thin as possible to maintain the wafer's low-effective dielectric constant. Because thicker TEOS layers improve process control for CMP integration, however, the ultimate thickness selected represents a compromise between these two competing functions. The “thick” TEOS layers resulting from this compromise require polishing composition with an efficient mask removal step with a controlled interconnect metal removal rate.

In summary, these semiconductor integration schemes require the selective removal of silicon oxide-containing layers with an effective removal rate and either stopping on the lower capping layer or on the dielectric. In view of these considerations, there is a desire to provide polishing compositions that permit controlled silicon oxide-containing layer removal. In addition, there is an ongoing desire to remove silicon oxide-containing layers, such as TEOS mask layers, with reduced defectivity.

In addition, since semiconductor fabricators rely upon different integration schemes and low k/ultra-low k materials, semiconductor customers have different requirements for the CMP slurries. These divergent integration schemes render formulating a universal polishing solution most difficult. Thus it is also efficacious to adjust the removal rate of silicon oxide-containing layers, cap layers, as well as the metal interconnect, such as copper to satisfy multiple integration schemes.

### STATEMENT OF THE INVENTION

An aspect of the invention includes an aqueous polishing composition useful for polishing semiconductor substrates comprising: 0.05 to 50 weight percent abrasive; and 0.001 to 2 weight percent lambda type carrageenan, the lambda type carrageenan having a concentration useful for accelerating TEOS removal rate.

Another aspect of the invention includes an aqueous polishing composition useful for polishing semiconductor substrates comprising: 0.1 to 50 weight percent abrasive; and 0.01 to 1.5 weight percent lambda type carrageenan, the lambda type carrageenan having a concentration useful for accelerating TEOS removal rate and useful for decreasing the removal rate of at least one coating selected from the group of SiC, SiCN and Si₃N₄.

Another aspect of the invention includes an aqueous polishing composition useful for polishing semiconductor substrates comprising: 0.1 to 50 weight percent silica abrasive; and 0.05 to 1 weight percent lambda type carrageenan, the lambda type carrageenan having a concentration useful for accelerating TEOS removal rate and useful for decreasing the removal rate of at least one coating selected from the group of SiC, SiCN and Si₃N₄.

Another aspect of the invention includes a method of polishing a semiconductor substrate including the step of polishing with an aqueous polishing composition, the composition including 0.05 to 50 weight percent abrasive; and 0.01 to 2 weight percent lambda type carrageenan, the lambda type carrageenan for removing TEOS and maintaining a hardmask layer selected from at least one of SiC, SiCN and Si₃N₄.

### DETAILED DESCRIPTION

It has been found that addition of a lambda carrageenan in a slurry with an abrasive can enhance the removal rate of silicon oxide containing materials. Carrageenans represent naturally occurring complex mixtures of sulfated polysaccharides extracted from red seaweed. In particular, Carrageenans are high molecular weight polysaccharides made up of repeating galactose units and 3,6 anhydrogalactose (3,6-AG), both sulfated and non-sulfated. There are three commercial types of carrageenan: Kappa, Iota and Lambda (κ, ι, and λ). The units are joined by alternating alph 1-3 and beta 1-4 glycosidic linkages. The primary difference, which influences the properties of kappa, iota and lambda, is the number and position of the ester sulfate groups on the repeating units. Each unit of lambda carrageenan contains an average of about 1.5 sulfate groups; each unit of iota-carrageenan contains an average of about 1 sulfate group, and each unit of kappa-carrageenan contains an average of about 0.5 sulfate groups. Basically, the lambda with more sulfated groups has less gelling potential. The lambda-carrageenan typically has greater than one sulfate group for each unit. The kappa-carrageenan, with more anhydrate linkages, has more gelling potential, due to its greater “kink” structure. The lambda-carrageenan serves to increase viscosity in commercial applications. Kappa forms brittle and firm gel, which is “non-curable” while iota forms “elastic” gel which is “reversible” after the gel has broken. Furthermore the one containing more sulfate groups is more water soluble or has a high water solubility. The addition of the more soluble lambda-carrageenan can enhance the removal rate of silicon oxide-containing layer.

The lambda-carrageenans are present in an amount of 0.001 weight percent to 2 weight percent. For purposes of this specification, all concentrations have values expressed in weight percent based upon the total weight of the polishing composition, unless specifically noted otherwise. Preferably, the lambda-carrageenan is present in an amount of 0.01 to 1.5 weight percent and most preferably, 0.05 to 1 weight percent.

The polishing composition contains 0.05 to 50 weight percent abrasive to facilitate silica removal or combined barrier and silica removal—depending upon the integration scheme, the polishing composition may serve to remove the mask layer or to first remove a barrier layer and then remove a silicon oxide-containing layer. The abrasive is preferably a colloidal abrasive. Example abrasives include inorganic oxides, metal borides, metal carbides, metal nitrides, polymer particles and mixtures comprising at least one of the foregoing. Suitable inorganic oxides include, for example, silica (SiO₂), alumina (Al₂O₃), zirconia (ZrO₂), ceria (CeO₂), manganese oxide (MnO₂), or combinations comprising at least one of the foregoing oxides. Modified forms of these inorganic oxides such as polymer-coated inorganic oxide particles and inorganic coated particles may also be utilized if desired. Suitable metal carbides, boride and nitrides include, for example, silicon carbide, silicon nitride, silicon carbonitride (SiCN), boron carbide, tungsten carbide, zirconium carbide, aluminum boride, tantalum carbide, titanium carbide, or combinations comprising at least one of the foregoing metal carbides, boride and nitrides. Diamond may also be utilized as an abrasive if desired. Alternative abrasives also include polymeric particles and coated polymeric particles. The preferred abrasive is silica.

It is desired to use the abrasive in an amount of 0.1 to 50 weight percent. Within this range, it is desirable to have the abrasive present in an amount of greater than or equal to 0.2 weight percent, and preferably greater than or equal to 0.5 weight percent. Also desirable within this range is an amount of less than or equal to 15 weight percent, and preferably less than or equal to 10 weight percent.

The abrasive has an average particle size of less than or equal to 150 nanometers (nm) for preventing excessive metal dishing and dielectric erosion. For purposes of this specification, particle size refers to the average particle size of the abrasive. It is desirable to use a colloidal abrasive having an average particle size of less than or equal to 100 mm, preferably less than or equal to 50 nm, and more preferably less than or equal to 40 nm. The least dielectric erosion and metal dishing advantageously occurs with colloidal silica having an average particle size of less than or equal to 40 nm. Decreasing the size of the colloidal abrasive to less than or equal to 40 nm, tends to improve the selectivity of the polishing composition; but it also tends to decrease the barrier removal rate. In addition, the preferred colloidal abrasive may include additives, such as dispersants, surfactants and buffers to improve the stability of the colloidal abrasive at acidic pH ranges. One such colloidal abrasive is colloidal silica from AZ Electronic Materials.

If the polishing composition does not contain abrasives, then pad selection and conditioning become more important to the chemical mechanical planarizing (CMP) process. For example, for some abrasive-free compositions, a fixed abrasive pad improves polishing performance.

The polishing composition may optionally contain a barrier removing agent, such as guanidine, formamidine or their derivatives to enhance the removal of barrier, such as tantalum, tantalum nitride, titanium and titanium nitride. The chemical mechanical planarizing composition can also optionally include complexing agents, chelating agents, pH buffers, biocides and defoaming agents.

Optionally, the removal rate of barrier layers, such as tantalum, tantalum nitride, titanium and titanium nitride is advantageously optimized by the use of the oxidizing agent. Suitable oxidizers include, for example, hydrogen peroxide, monopersulfates, iodates, magnesium perphthalate, peracetic acid and other peracids, persulfates, bromates, periodates, nitrates, iron salts, cerium salts, manganese (Mn) (III), Mn (IV) and Mn (VI) salts, silver salts, copper salts, chromium salts, cobalt salts, halogens, hypochlorites, or combinations comprising at least one of the foregoing oxidizers. The preferred oxidizer is hydrogen peroxide. It is to be noted that the oxidizer is typically added to the polishing composition just prior to use and in such instances the oxidizer is contained in a separate package.

It is desirable to use an amount of 0 to 10 wt % oxidizer. Within this range, it is desirable to have oxidizer at an amount of greater than or equal to 0.1 wt %. Also desirable within this range is an amount of less than or equal to 5 wt % oxidizer. Most preferably, the composition contains 0.1 to 5 wt % oxidizer. Adjusting the amount of oxidizer, such as peroxide can also control the metal interconnect removal rate. For example, increasing the peroxide concentration increases the copper removal rate. Excessive increases in oxidizer, however, provide an adverse impact upon polishing rate.

The polishing composition may have either an acidic pH or alkaline pH. Suitable metals used for the interconnect include, for example, copper, copper alloys, gold, gold alloys, nickel, nickel alloys, platinum group metals, platinum group metal alloys, silver, silver alloys, tungsten, tungsten alloys and mixtures comprising at least one of the foregoing metals. The preferred interconnect metal is copper. In acidic polishing compositions or alkaline polishing compositions and slurries that utilize oxidizers such as hydrogen peroxide, both the copper removal rate and the static etch rate are high primarily because of oxidation of the copper. In order to reduce the removal rate of the interconnect metal the polishing composition employs a corrosion inhibitor. The corrosion inhibitors function to reduce removal of the interconnect metal. This facilitates improved polishing performance by reducing the dishing of the interconnect metal.

The inhibitor is typically present in an amount up to 6 wt %—the inhibitor may represent a single or a mixture of inhibitors to the interconnect metal. Within this range, it is desirable to have an amount of inhibitor greater than or equal to 0.0025 wt %, preferably greater than or equal to 0.15 wt %. Also desirable within this range is an amount of less than or equal to 1 wt %, preferably less than or equal to 0.5 wt %. The preferred corrosion inhibitor is benzotriazole (BTA). The optimal amount of inhibitor in an acidic composition may be higher than that in an alkaline pH polishing composition.

Additional corrosion inhibitors include surfactants such as, for example, anionic surfactants, zwitterionic, nonionic surfactants, amphoteric surfactants and polymeric surfactants, or organic compounds, such as azoles. Suitable anionic surfactants include, for example, surfactants having a functional group, such as a sulfonate, a sulfate, a carboxylate, a phosphate, or a derivative of these functional groups, or combinations comprising at least one of the foregoing surfactants. A preferred anionic surfactant is sodium dodecylbenzenesulfonate. Suitable nonionic surfactants include, for example, silicon-based compounds, fluorine-based compounds, an ester, an ethylene oxide, an alcohol, an ethoxylate, an ether, a glycoside, or a derivative of these compounds, or a combination comprising at least one of the foregoing nonionic surfactants. Suitable amphoteric surfactants or polymers include, for example, polycarboxylates and their derivatives, polyacrylamides and their derivatives, cellulose, polyvinylalcohols and their derivatives, and polyvinylpyrrolidones and their derivatives. Suitable azoles that may be used as an inhibitor or in an inhibitor mixture include, for example, tolytriazole (TTA), imidazole and mixtures thereof. The most preferred secondary corrosion inhibitor is tolytriazole.

The polishing composition also includes inorganic or organic pH adjusting agents to reduce the pH of the polishing composition to an acidic pH or to increase the pH to an alkaline pH. Suitable inorganic pH reducing agents include, for example, nitric acid, sulfuric acid, hydrochloric acid, phosphoric acid, or combinations comprising at least one of the foregoing inorganic pH reducing agents. Suitable pH increasing agents include one of metal hydroxides, ammonium hydroxide, or nitrogen-containing organic base or combination of foregoing pH increasing agents.

The polishing composition operates at either an acidic pH or an alkaline pH. It is preferable to have the pH of the polishing composition between 1 and 14. Within this range it is desirable to have a pH of greater than or equal to 2 and lower than or equal to 12. The most preferred pH for the polishing composition is 3 to 10.

Optionally, the polishing composition may contain a chelating or complexing agent to adjust the copper removal rate relative to the barrier metal removal rate. The chelating agent improves the copper removal rate by forming a chelated metal complex with copper. Suitable chelating agents include, for example, carboxylic acid, an amino-carboxylic acid and derivatives thereof, or combinations comprising at least one of the foregoing chelating agents. Preferably, the chelating agent is present in the polishing composition in an amount of less than or equal to 2 wt %. Optionally, the polishing composition can also include buffering agents such as various organic and inorganic acids, and amino acids or their salts with a pKa in the pH range of 1.5 to less than 13. Optionally, the polishing composition can further include defoaming agents, such as an non-ionic surfactants including esters, ethylene oxides, alcohols, ethoxylate, silicon compounds, fluorine compounds, ethers, glycosides and their derivatives. The defoaming agent may also be an amphoteric surfactant.

The polishing composition enables the CMP apparatus to operate with a low pressure of 2.5 to 15 kilopascals (kPa). Within this range, a pressure of 3 to 12 kPa, is preferred. The low CMP pad pressure improves polishing performance by reducing scratching and other undesired polishing defects and minimizes damage to fragile materials. For example, low dielectric constant materials fracture and delaminate when exposed to high stresses. Further, the high barrier metal removal rate obtained by the polishing composition enables effective barrier metal removal rates and silicon oxide-containing layer, such as TEOS, removal rates using a low abrasive concentration and a small abrasive particle size. In an exemplary embodiment, the polishing composition can be adjusted or tuned so as to advantageously achieve a high barrier removal rate without any destruction to the silicon oxide-containing layer. It can also advantageously be tuned to remove the silicon oxide-containing layer without any damage to the low k or ultra-low k dielectric layer.

The composition accelerates TEOS removal and decreases removal of at least one coating selected from the group consisting of SiC, SiCN and Si₃N₄ for at least one polishing pressure of less than 21.7 kPa (3 psi) as measured with a porous-filled polyurethane polishing pad pressure measured normal to a wafer. Preferably the at least one coating selected from the group consisting of SiC, SiCN and Si₃N₄ is a cap. For purposes of the specification, comparative removal refers to removal rates as measured with a porous-filled polyurethane polishing pad pressure measured normal to a wafer. A particular polishing pad useful for determining selectivity is the IC1010™ porous-filled polyurethane polishing pad. Since the composition will operate at a variety of polishing pressures, these data are for illustrating the efficacy of the composition, not for describing a specific operating pressure for the use of the composition. The polishing composition optionally has a TEOS to cap selectivity of at least 2 to 1 as measured with a porous-filled polyurethane polishing pad pressure measured normal to a wafer with at least one polishing pressure less than 21.7 kPa. The integration scheme selected controls TEOS selectivity.

In addition to mask to cap selectivity, the solution optionally has barrier removal selectivity with respect to metal interconnects—it removes barrier materials at a greater rate than metal interconnects, such as copper with a porous-filled polyurethane polishing pad pressure measured normal to a wafer with at least one polishing pressure less than 21.7 kPa. Optionally, the polishing composition has a tantalum nitride to copper selectivity of greater than or equal to 2 to 1 as measured with a porous-filled polyurethane polishing pad pressure measured normal to a wafer with at least one polishing pressure less than 21.7 kPa. Optionally, the polishing composition has a tantalum nitride to copper selectivity of greater than or equal to 5 to 1 as measured with a porous-filled polyurethane polishing pad pressure measured normal to a wafer with at least one polishing pressure less than 21.7 kPa. This high level of selectivity allows a chip manufacturer to remove material from the barrier layer without removing excess interconnect material.

Alternatively, the process may stop on the dielectric layer with an additional additive. Typical dielectric materials include silicon oxide-containing materials derived from silanes such as tetratethylorthosilicate (TEOS), low k and/or ultra-low k organic materials, CORAL® CVD SiOC commercially available from Novellus. Optionally, addition an anionic surfactant or nonionic surfactant in the basic compositions containing a lambda-carrageenan described in this invention will effectively lower the removal rate of SiOC, without affecting other film removal rate.

### EXAMPLES

### Example 1

The aqueous slurries tested contained Marine Colloids™ carrageenan (kappa, iota, iota with Ca and lambda) supplied from FMC, Philadelphia, Pa. The specific lambda type carrageenan was Viscarin GP 209F from FMC. This experiment was conducted to determine the polishing performance of the polishing composition with varied carrageenan types and concentrations. This Example and all other Examples used a Strausbaugh polishing machine with an IC1010 polishing pad (Rohm and Haas Electronic Materials CMP Technologies) under downforce conditions of about 2 psi (13.8 kPa) and a polishing slurry flow rate of 200 cc/min, a platen speed of 120 RPM and a carrier speed of 114 RPM polishing the sample wafers (200 mm). All polishing slurries had a pH adjusted with KOH or HNO₃ and all slurries were made with a balance of deionized water. In the Examples, letters identify the comparative compositions and numbers represent embodiments of the invention.

TABLE 1

| | | | | | | | | | |
|---|---|---|---|---|---|---|---|---|---|
| | Silica | | GHC | TaN | TEOS | CDO | SiCN | Cu | SiN |
| Sample | (wt %) | pH | (wt %) | (Å/min) | (Å/min) | (Å/min) | (Å/min) | (Å/min) | (Å/min) |

Kappa-Carrageenan (wt %)

| | | | | | | | | | | |
|---|---|---|---|---|---|---|---|---|---|---|
| A | 2 | 4.0 | 0 | 1 | 1552 | 233 | 306 | 404 | 92 | 376 |
| B | 2 | 4.0 | 0.10 | 1 | 1887 | 280 | 322 | 117 | 240 | 254 |
| C | 2 | 4.0 | 0.30 | 1 | 1502 | 78 | 304 | 109 | 369 | 176 |

Iota-Carrageenan (wt %)

| | | | | | | | | | | |
|---|---|---|---|---|---|---|---|---|---|---|
| D | 2 | 4.0 | 0.10 | 1 | 1728 | 221 | 164 | 168 | 284 | 241 |
| E | 2 | 4.0 | 0.30 | 1 | 1555 | 234 | 183 | 53 | 422 | 185 |
| F | 2 | 4.0 | 0 | 1 | 1553 | 227 | 180 | 355 | 101 | 441 |

Iota-Carrageenan with Ca (wt %)

| | | | | | | | | | | |
|---|---|---|---|---|---|---|---|---|---|---|
| G | 2 | 4.0 | 0.10 | 1 | 1695 | 224 | 217 | 105 | 295 | 200 |
| H | 2 | 4.0 | 0.30 | 1 | 1604 | 255 | 295 | 53 | 409 | 173 |

Lambda-Carrageenan (wt %)

| | | | | | | | | | |
|---|---|---|---|---|---|---|---|---|---|
| I | 2 | 4.0 | 0 | 1 | 1351 | 257 | 175 | 426 | 105 |
| 1 | 2 | 4.0 | 0.01 | 1 | 1781 | 277 | 178 | 173 | 200 |
| 2 | 2 | 4.0 | 0.05 | 1 | 1883 | 321 | 185 | 67 | 243 |
| 3 | 2 | 4.0 | 0.1 | 1 | 1783 | 403 | 192 | 59 | 289 |
| 4 | 2 | 4.0 | 0.2 | 1 | 1136 | 379 | 227 | 60 | 262 |
| 5 | 2 | 4.0 | 0.4 | 1 | 1426 | 460 | 247 | 63 | 341 |
| J | 4 | 2.5 | 0 | 0 | 2000 | 224 | 532 | 1527 | 121 |
| 6 | 4 | 2.5 | 0.1 | 0 | 477 | 692 | 904 | 105 | 99 |
| 7 | 4 | 2.5 | 0.5 | 0 | 469 | 640 | 602 | 133 | 183 |

GHC = guanidine hydrochloride. All samples contained PL150H25 30 nm average particle size silica from AZ Electronic Materials, 0.15 wt % Benzotriazole and 0.5 wt % H₂O_{2.}, and CDO was Coral ™ dielectric from Novellus Systems, Inc.

This Example shows that lambda-carrageenan increases TEOS removal rate and decreases SiCN removal rate with no adverse impact on CDO rate. The kappa, iota and iota with Ca type carrageenans did not have a significant effect on TEOS removal rate.

### Example 2

This Example tested effectiveness at alkaline pH levels.

TABLE 2

| | | | | Lambda- | | | | |
|---|---|---|---|---|---|---|---|---|
| | Silica | | GHN | Carrageenan | TaN | TEOS | CDO | Cu |
| Sample | (wt %) | pH | (wt %) | (wt %) | (Å/min) | (Å/min) | (Å/min) | (Å/min) |
| L | 10 | 8 | 0.4 | 0 | 952 | 528 | 863 | 25 |
| 17 | 10 | 8 | 0.4 | 0.2 | 671 | 703 | 1818 | 115 |
| 18 | 10 | 8 | 0.4 | 0.4 | 602 | 725 | 1704 | 129 |
| 19 | 10 | 8 | 0 | 0 | 300 | 260 | 402 | 88 |
| 20 | 10 | 8 | 0 | 0.2 | 697 | 652 | 1172 | 110 |
| 21 | 10 | 8 | 0 | 0.4 | 635 | 629 | 989 | 165 |
| 22 | 10 | 8 | 0 | 0.6 | 389 | 237 | 420 | 135 |

GHN = guanidine hydronitrate. All samples included 0.10 wt % benzotriazole; 0.01 wt % Kordex MLX biocide (methyl-4-isothiazolin-3-one 7.0 to <10.0 wt %); and 10 wt % Klebosol II 50 nm average particle size silica from AZ Electronic Materials, and CDO was Coral ™ dielectric from Novellus Systems, Inc.

The lambda-carrageenan also increased removal rate for CDO in the guanidine hydronitrate formulations and decreased CDO removal rate for the formulation free of guanidine hydronitrate. Furthermore, the additive is effective for increasing TEOS rate with or without the addition of guanidine.

### Example 3

This Example included polishing of Si₃N₄ film with silica abrasive concentrations from 1 to 4 wt %.

TABLE 3

| | | Lamda- | | | | | | | |
|---|---|---|---|---|---|---|---|---|---|
| | Silica | Carrageenan | TaN | TEOS | CDO | SiCN | Cu | Si₃N₄ | TEOS/Si₃N₄ |
| Sample | (wt %) | (wt %) | (Å/min) | (Å/min) | (Å/min) | (Å/min) | (Å/min) | (Å/min) | Ratio (Å/min) |
| M | 2 | 0 | 1552 | 233 | 306 | 404 | 92 | 376 | 0.6 |
| 23 | 1 | 0.4 | 716 | 249 | 428 | 62 | 146 | 39 | 6.4 |
| 24 | 2 | 0.4 | 1463 | 457 | 339 | 52 | 258 | 74 | 6.2 |
| 25 | 4 | 0.4 | 1635 | 635 | 632 | 96 | 266 | 122 | 5.2 |

All samples contained PL150H25 30 nm average particle size silica from AZ Electronic Materials, 0.15 wt % Benzotriazole, 1 wt % guanidine hydrochloride and 0.5 wt % H₂O_{2.} at a pH of 4, and CDO was Coral ™ dielectric from Novellus Systems, Inc.

The above Table demonstrates that the lambda-carrageenan is also effective for suppressing silicon nitride layer removal rate.

### Example 4

The following Example tested the additive's effectiveness at alkaline pH levels.

TABLE 4

| | | | Lambda- | | | | | |
|---|---|---|---|---|---|---|---|---|
| | | Silica | Carrageenan | GHC | TaN | TEOS | CDO | Cu |
| Sample | pH | (wt %) | (wt %) | (wt %) | (Å/min) | (Å/min) | (Å/min) | (Å/min) |
| N | 8 | 10 | 0 | none | 300 | 260 | 402 | 88 |
| 26 | 8 | 10 | 0.2 | none | 697 | 652 | 1172 | 110 |
| 27 | 8 | 10 | 0.4 | none | 635 | 629 | 989 | 165 |
| 28 | 8 | 10 | 0.2 | 0.4 | 679 | 710 | 1806 | 247 |
| 29 | 7 | 10 | 0.2 | 0.4 | 723 | 706 | 1783 | 124 |
| 30 | 6 | 10 | 0.2 | 0.4 | 745 | 672 | 1595 | 146 |

GHC = guanidine hydrochloride. All samples included 0.10 wt % benzotriazole; 0.01 wt % Kordex MLX biocide (methyl-4-isothiazolin-3-one 7.0 to <10.0 wt %); and 10 wt % Klebosol II 50 nm average particle size silica from AZ Electronic Materials, and CDO was Coral ™ dielectric from Novellus Systems, Inc.

At the pH levels tested the lambda-carrageenan increased TEOS removal rate with a corresponding increase in CDO and TaN removal rates. Furthermore, the lambda-carrageenan functioned at the alkaline pH levels tested.

### Example 5

This Example tested the compatibility of lambda-carrageenan with another surfactant.

TABLE 5

| | | Lambda- | | Disponil FES 77 | | | | |
|---|---|---|---|---|---|---|---|---|
| | | Carrageenan | GHN | IS Surfactant | TaN | TEOS | CDO | Cu |
| Sample | pH | (wt %) | (wt %) | (wt %) | (Å/min) | (Å/min) | (Å/min) | (Å/min) |
| 31 | 8 | 0.2 | 0.4 | 0 | 654 | 760 | 2046 | 98 |
| 32 | 8 | 0.2 | 0.4 | 0.001 | 676 | 766 | 1725 | 147 |
| 33 | 8 | 0.2 | 0.4 | 0.003 | 617 | 713 | 1388 | 122 |
| 34 | 8 | 0.2 | 0.4 | 0.007 | 659 | 688 | 562 | 166 |
| 35 | 8 | 0.2 | 0.4 | 0.01 | 629 | 681 | 332 | 332 |
| 36 | 8 | 0.2 | 0.4 | 0.01 | 629 | 697 | 318 | 122 |
| 37 | 8 | 0.2 | 0.4 | 0.03 | 540 | 444 | 98 | 217 |

GHN = guanidine hydronitrate. All samples included 0.10 wt % benzotriazole; 0.01 wt % Kordex MLX biocide (methyl-4-isothiazolin-3-one 7.0 to <10.0 wt %); Disponil FES77 IS is an anionic surfactant with its chemical description of sodium fatty alcohol polyglycol ether sulfate, manufactured by Cognis Chemicals Group.; and 10 wt % Klebosol II 50 nm average particle size silica from AZ Electronic Materials, and CDO was Coral ™ dielectric from Novellus Systems, Inc.

This Example illustrates addition of an anionic surfactant to suppress CDO removal rate with little adverse impact on TEOS removal rate. This demonstrates the compatibility of the lambda-carrageenan with anionic surfactants.

From the above experiments it may be seen that the use of the lambda-carrageenan in the polishing compositions permits the differential removal rates for the silicon oxide-containing layers when compared with the removal rates for the barrier layers. This advantageously permits the rapid removal of one layer over another, such as TEOS in comparison to SiCN. For example, for a semiconductor having a mask layer and a cap layer, it optionally permits the selectivity of mask to cap to be greater than or equal to 2 to 1 or even greater than or equal to 5 to 1. The selectivity ratios are applicable to TEOS masks deposited on SiC, SiCO, Si₃N₄ or SiCN cap layers. They are also applicable to single masks as shown in the Table 6 below. The polishing composition can also advantageously be tuned to remove the silicon oxide-containing layer without any damage to the low k or ultra-low k dielectric layer. The ability of these polishing compositions to remove various layers of the semiconductor substrate without any damage to the silicon oxide-containing layer, the low k and/or ultra-low k dielectric layer is shown in the Table 6 below.

TABLE 6

| | | | | Removal Rate |
|---|---|---|---|---|
| Integration | | Interconnect | Integration | (RR) |
| Scheme # | Layer | structures | schemes for CMP | requirements |
| 1 | Dual | TaN/TEOS/SiCN/Low k or | Polish TaN and TEOS layers; stop | High RR for TaN and TEOS layers; |
| | coatings | ultra-low k dielectric layer | polishing on SiCN and low k or | Low RR for SiCN and low k or |
| | | | ultra-low k dielectric layer | ultra-low k dielectric layer |
| 2 | Single | TaN/TEOS (or SiCN)/Low k or | Polish TaN and TEOS (or SiCN)layers; | High RR for TaN and TEOS (or SiCN) |
| | coating | ultra-low k dielectric layer | stop polishing on low k or ultra- | layers; Low RR for low k or ultra- |
| | | | low k dielectric layer | low k dielectric layer |
| 3 | Single | TaN/TEOS (or SiCN)/Low k or | Polish TaN layer; stop polishing on | High RR for TaN; Low RR for TEOS |
| | coating | ultra-low k dielectric layer | TEOS (or SiCN) and low k or ultra- | (or SiCN) and low k or ultra-low |
| | | | low k dielectric layer | k dielectric layer |
| 4 | No | TaN/Low k or ultra-low k | Polish TaN layer; stop polishing on | High RR for TaN; Low RR for low k |
| | coating | dielectric layer | low k or ultra-low k dielectric layer | or ultra-low k dielectric layer |

Table 6 shows various integration schemes that may be employed for selectively removing certain desired layers from a semiconductor substrate. For example, integration scheme 1 shows how the polishing composition may be advantageously utilized to selectively remove the TaN and TEOS layers from an interconnect structure comprising TaN, TEOS, SiCN and an ultra-low k dielectric layer respectively. The polishing composition removes the TaN and TEOS layer at a higher rate than the SiCN and CDO layer, thereby preserving the SiCN and the ultra-low k dielectric layer.

The polishing composition is utilized to adjust the removal rate of silicon oxide-containing layers and optionally barrier layers from interconnect structures in integrated circuit devices. It can be adjusted or tuned so as to achieve a high silicon oxide-containing layer removal with reduced dishing to the interconnect metal or with stopping on a cap layer, such as a SiCN, or Si₃N₄ cap layer. Optionally, the method includes removing a barrier layer with the aqueous polishing composition before removing the silicon oxide-containing layer. In addition, if the silicon oxide-containing layer is a top TEOS layer deposited on a bottom layer and the bottom layer is a SiC, SiCN, Si₃N₄ or SiCO, then the composition can remove the top layer and leave at least a portion of the bottom layer. This selective TEOS removal is particularly effective for protecting low k and ultra-low k dielectrics with a cap layer.

1. An aqueous polishing composition useful for polishing semiconductor substrates comprising:
0.05 to 50 weight percent abrasive; and
0.001 to 2 weight percent lambda type carrageenan, the lambda type carrageenan having a concentration useful for accelerating TEOS removal rate.

2. The composition of claim 1, wherein the lambda type carrageenan is useful for decreasing the removal rate of at least one coating selected from the group of SiC, SiCN and Si₃N₄.

3. The composition of claim 1, wherein the abrasive is selected from at least one of inorganic oxides, metal borides, metal carbides, metal nitrides and polymer particles.

4. An aqueous polishing composition useful for polishing semiconductor substrates comprising:
0.1 to 50 weight percent abrasive; and
0.01 to 1.5 weight percent lambda type carrageenan, the lambda type carrageenan having a concentration useful for accelerating TEOS removal rate and useful for decreasing the removal rate of at least one coating selected from the group of SiC, SiCN and Si₃N₄.

5. The composition of claim 4, wherein the lambda type carrageenan is useful for decreasing the removal rate of SiCN.

6. The composition of claim 4, wherein the abrasive is selected from at least one of alumina, ceria and silica.

7. An aqueous polishing composition useful for polishing semiconductor substrates comprising:
0.1 to 50 weight percent silica abrasive; and
0.05 to 1 weight percent lambda type carrageenan, the lambda type carrageenan having a concentration useful for accelerating TEOS removal rate and useful for decreasing the removal rate of at least one coating selected from the group of SiC, SiCN and Si₃N₄.

8. The composition of claim 7, wherein the lambda type carrageenan is useful for decreasing the removal rate of SiCN.

9. The composition of claim 4, wherein the composition includes a benzotriazole corrosion inhibitor.

10. A method of polishing a semiconductor substrate including the step of polishing with an aqueous polishing composition, the composition including 0.05 to 50 weight percent abrasive; and 0.01 to 2 weight percent lambda type carrageenan, the lambda type carrageenan for removing TEOS and maintaining a hardmask layer selected from at least one of SiC, SiCN and Si₃N₄.
